(19) United States
(12) Patent Application Publication
(10) Pub. No.: US 2009/0010046 A1
(43) Pub. Date: Jan. 8, 2009

(54) MAGNETIC MEMORY DEVICE WITH NON-RECTANGULAR CROSS SECTION CURRENT CARRYING CONDUCTORS

(76) Inventor: Krishnakumar Mani, San Jose, CA (US)

Correspondence Address: HAHN AND MOODLEY, LLP, P.O. BOX 52050, MINNEAPOLIS, MN, 55402, US

(21) Appl. No.: 12/165,602

(22) Filed: Jun. 30, 2008

Related U.S. Application Data
(60) Provisional application No. 60/946,966, filed on Jun. 28, 2007.

(51) Int. Cl. G11C 11/16

(52) U.S. Cl. 365/158

(57) ABSTRACT

Embodiments of the invention magnetic memory device, comprising: a plurality of magnetic memory cells, each comprising: a magnetic memory element capable of being flipped between two stable spin orientations under the influence of an applied magnetic field; and current-carrying conductors proximate the magnetic element to carry a current that induces said applied magnetic field, wherein the current-carrying conductors have a non-rectangular cross section; and a read circuit for reading data from the selected magnetic memory cells.

This application claims the benefit of priority to U.S. Provisional Patent Application No. 60/946,966 filed Jun. 28, 2007, and entitled “Enhanced Magnetic Field and Reduced Power Consumption Due to Current Carrying Conductor(s) of Non-Rectangular Cross Section”, the specification of which is hereby incorporated by reference.

### FIELD

Embodiments of the invention relate to magnetic memory cells and devices built using magnetic memory cells.

### BACKGROUND

Magnetic solid state memory (magnetic memory) has recently emerged as a potential replacement for various types of non-volatile solid state memories. With modern solid state magnetic memory write operations are performed by passing current through a matrix of bit lines and word lines. The bit lines and word lines essentially form a grid, and magnetic storage elements are arranged at or proximate to the intersections of the various bit lines and word lines. The current induces a magnetic field around each of the lines, and the magnetic field induced by the combination of currents in the word lines and the bit lines is sufficient to change the orientation of the addressed magnetic elements.

### SUMMARY OF THE INVENTION

In one embodiment, the invention discloses enhancing the magnetic field produced by current-carrying conductors (i.e. the word and bit lines) in a magnetic memory cell by using current-carrying conductors of non-rectangular cross section. The current-carrying conductors may have a triangular or a trapezoidal cross-section.

In another embodiment, the invention discloses a magnetic memory cell comprising a magnetic element capable of being flipped between two stable spin orientations under influence of an applied magnetic field; and current-carrying conductors proximate the magnetic element to carry a current that induces said applied magnetic field, wherein the current-carrying conductors have a non-rectangular cross section. The current-carrying conductors may have a triangular or a trapezoidal cross-section. In one embodiment, the magnetic element may be magneto-resistive and may comprise a Magnetic Tunnel Junction. The magnetic memory cell may be a random access memory. In one embodiment, the magnetic memory may be a read-only memory.

In another embodiment, the invention discloses a manufacturing sequence for manufacturing a magnetic memory cell as aforesaid.

Other aspects of the invention will be apparent from the detailed description below:

### BRIEF DESCRIPTION OF THE DRAWINGS

FIG. 1 shows a current-carrying conductor of triangular cross-section, in accordance with one embodiment of the invention, and a magnetic field strength fall off curve for a magnetic field induced by currents in said current-carrying conductor.

FIG. 2 shows a current-carrying conductor of rectangular cross-section, in accordance with one embodiment of the invention, and a magnetic field strength fall off curve for a magnetic field induced by currents in said current-carrying conductor.

FIG. 3 illustrate the geometry of particular triangular, and trapezoidal current-carrying conductors of the present invention used to in illustrative magnetic field calculations.

FIG. 4 shows a contour map of magnetic field strength for a magnetic field in the vicinity of a rectangular cross section current-carrying conductor.

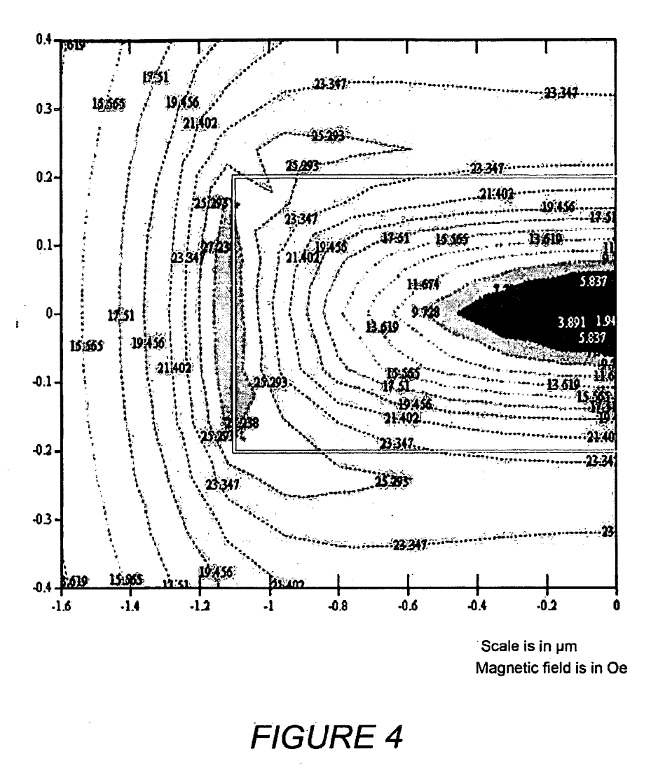

FIG. 5 shows a contour map of magnetic field strength for a magnetic field in the vicinity of a triangular cross section current-carrying conductor.

FIG. 6 shows a contour map of magnetic field strength for a magnetic field in the vicinity of a trapezoidal cross section current-carrying conductor.

FIG. 7 illustrates some possible cross sectional shapes for current-carrying conductors, in accordance with different embodiments of the invention.

FIG. 8 shows 3 dimensional view of a 2×2 array of MRAM cells built with trapezoidal conductors, on accordance with one embodiment of the invention.

FIG. 9 illustrates the process flow to build conductors of trapezoidal cross sections, in accordance with one embodiment of the invention.

### DETAILED DESCRIPTION

In the following description, for purposes of explanation, numerous specific details are set forth in order to provide a thorough understanding of the invention. It will be apparent, however, to one skilled in the art that the invention can be practiced without these specific details.

Reference in this specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

Existing magnetic memory architectures use magnetic fields generated by current-carrying conductors to change the state of a magnetic element between “0” and “1”. The current carrying conductors generally have a rectangular cross-section. In one embodiment, a magnetic memory architecture is disclosed wherein the current-carrying conductors have a non-rectangular cross-section. In accordance with different embodiments of the invention, said current-carrying conductors may have a triangular or a trapezoidal cross section. Advantageously, the magnetic fields generated by said current-carrying conductors of non-rectangular cross section are greater than that generated comparable current-carrying conductors of rectangular cross section, when measured at a point directly above. For example, in one embodiment, the magnetic field over a current-carrying conductor of triangular cross-section is roughly 56% greater that over a comparable current-carrying conductor of rectangular cross section. Because greater magnetic fields may be produced using current-carrying conductors of non-rectangular cross section, the currents used to create the magnetic fields can be smaller, thus enabling low energy magnetic memory devices.

Advantageously, the magnetic fields generated by the non-rectangular cross section current-carrying conductors of the present is more focused that the magnetic fields generated by similar conductors of rectangular cross-section. In other words, the magnetic field is focused around the conductor itself and declines sharply as one moves away from the conductor.

When the non-rectangular current-carrying conductors disclosed herein are used in Magnetic Random Access Memories, advantageously, there is a reduction in disturbances due to magnetic fields from neighboring memory cells. This significantly increases the reliability of the memory cells (due to better immunity to data loss) and increases the memory cell density.

Advantageously, mobile devices, such as mobile phones, Personal Digital Assistants (PDA's), digital cameras, etc. that use the magnetic memory device will have very low power consumption.

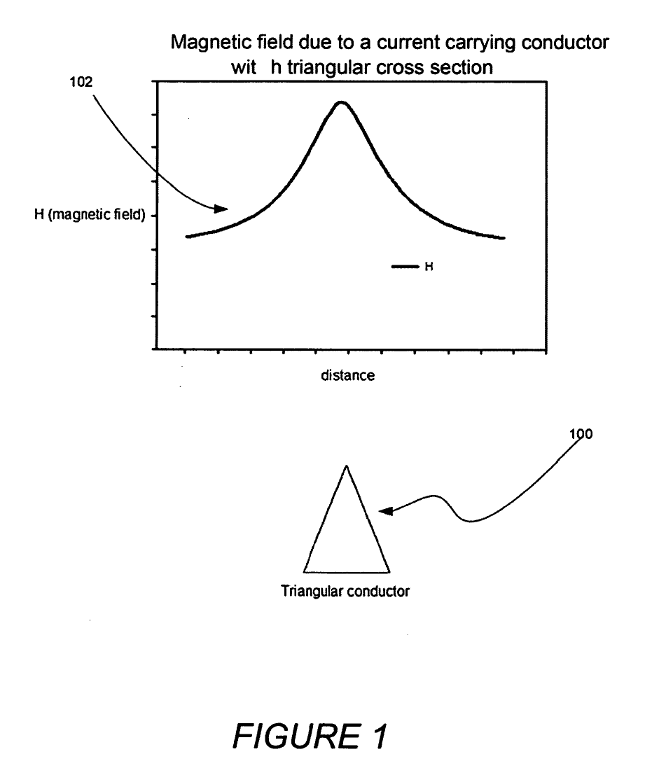

Referring now to FIG. 1 of the drawings, there is show a current carrying conductor 100, in accordance with one embodiment of the invention. FIG. 1 also shows a plot 102 of a magnetic field strength against distance for a magnetic field generated by current flowing through the conductor 100. As will be seen the plot 102 has a peak over the conductor 100, but falls symmetrically as one moves away from the conductor 100.

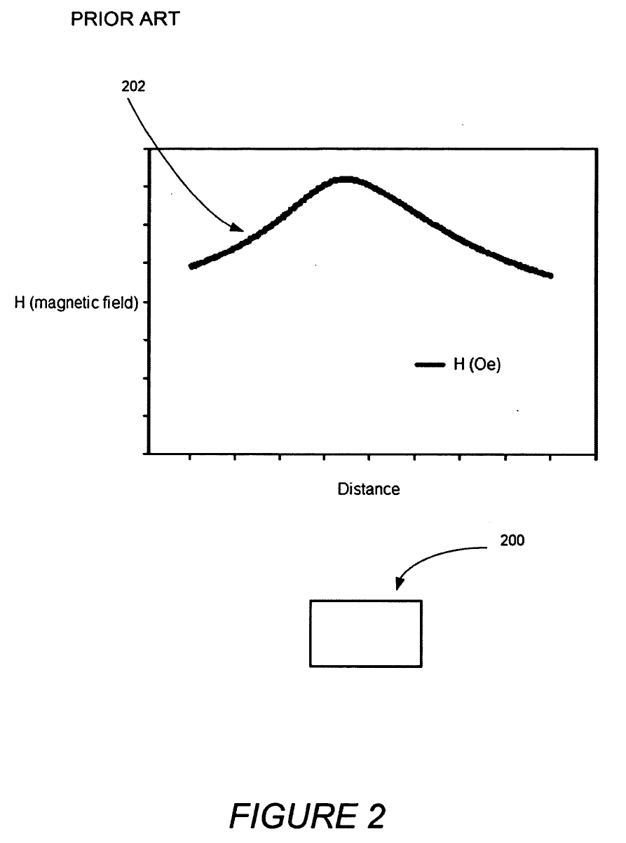

For comparative purposes, FIG. 2 shows a conductor 200 of rectangular cross section, in accordance with the prior art. Referring to FIG. 2, it will be seen that a plot 202 of magnetic field strength against distance for the conductor 200 has less of a peak than the plot 102. Thus, the magnetic field produced by the conductor 200 is less intense than the field produced the conductor 100. Moreover, it will be seen that the peak in the curve 102 is narrower that the peak in the curve 202. This shows that the magnetic field for the conductor 100 is more focused than the magnetic field for the conductor 200. Thus, a magnetic memory that has current carrying conductors of triangular cross section will suffer from less disturbance between magnetic memory cells due to field effects from neighboring cells as described above.

In general, embodiments of the invention disclose the use on non-rectangular cross section current carrying conductors in the construction of magnetic memory cells.

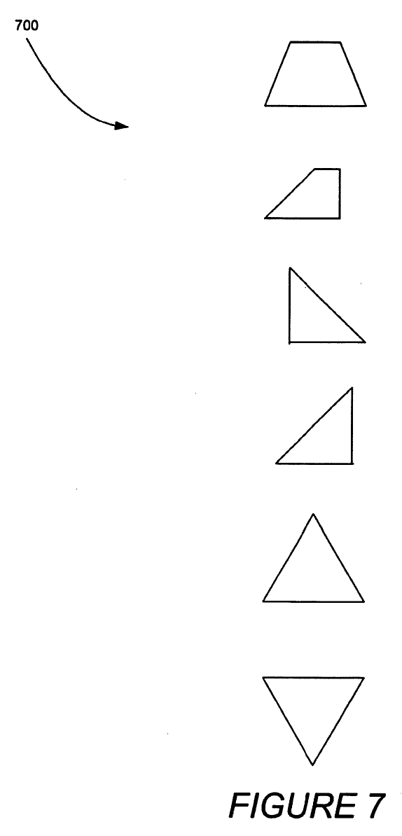

Other examples on non-rectangular cross section current carrying conductors include conductors with the cross sections selected from the group 700 of cross sections shown in FIG. 7 of the drawings.

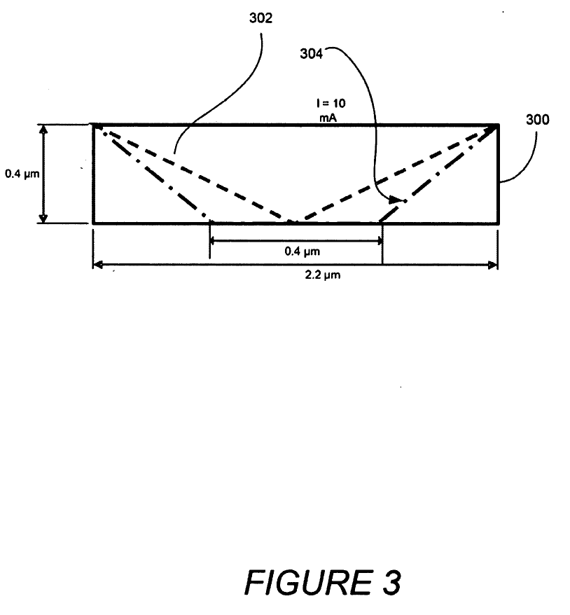

FIG. 3 of the drawings shows the geometry for rectangular cross section conductor 300, a triangular cross section conductor 302, and a trapezoidal conductor 306. The magnetic field for a given current at about 0.2 μm distance from the center of the conductors for the rectangular, trapezoidal and triangular conductors are 25 Oersted, 32 Oersted, and 39 Oersted, respectively. In other words, the triangular conductor 302 generates 56% (39 Oersted) more magnetic field strength compared to a conductor 300 of rectangular cross section. Moreover, the trapezoidal conductor 304 yields 28% more magnetic field strength compared to rectangular conductor 300.

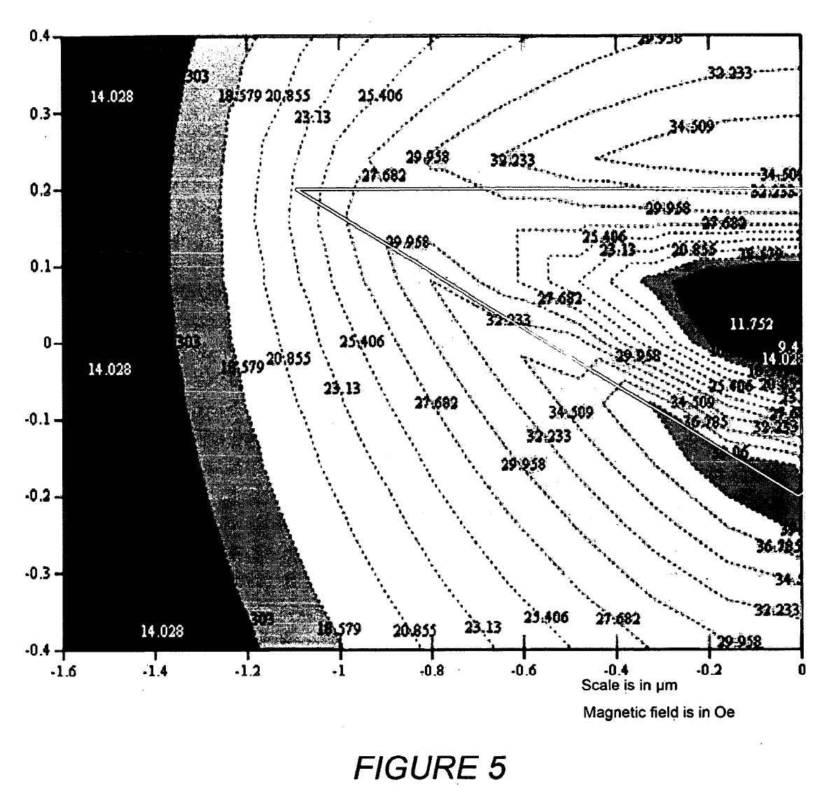

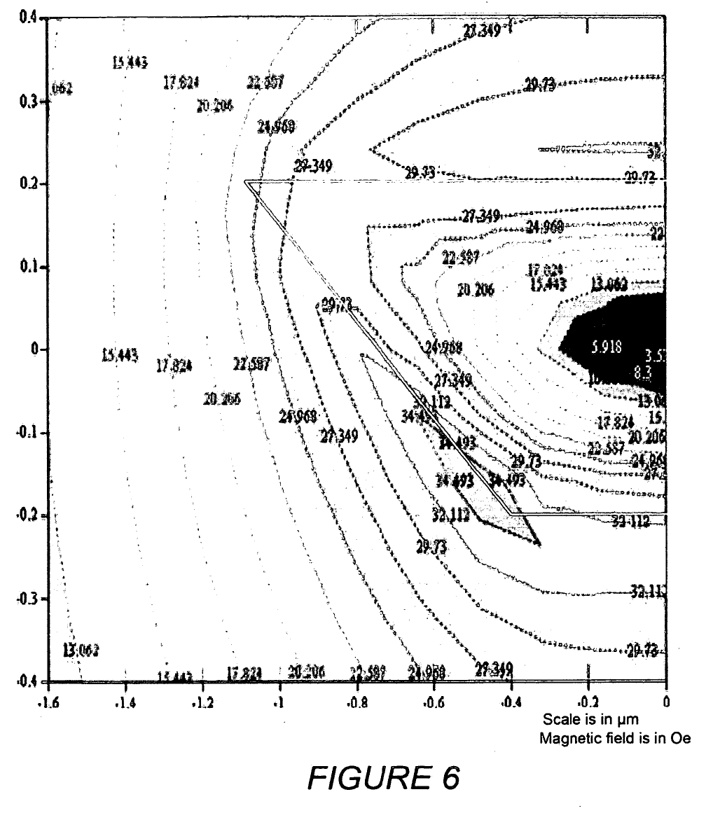

FIGS. 5, 6, and 7 of the drawings show the magnetic field strengths around the rectangular conductor 300, the triangular conductor 302, and the trapezoidal conductor 304, respectively for illustrative purposes

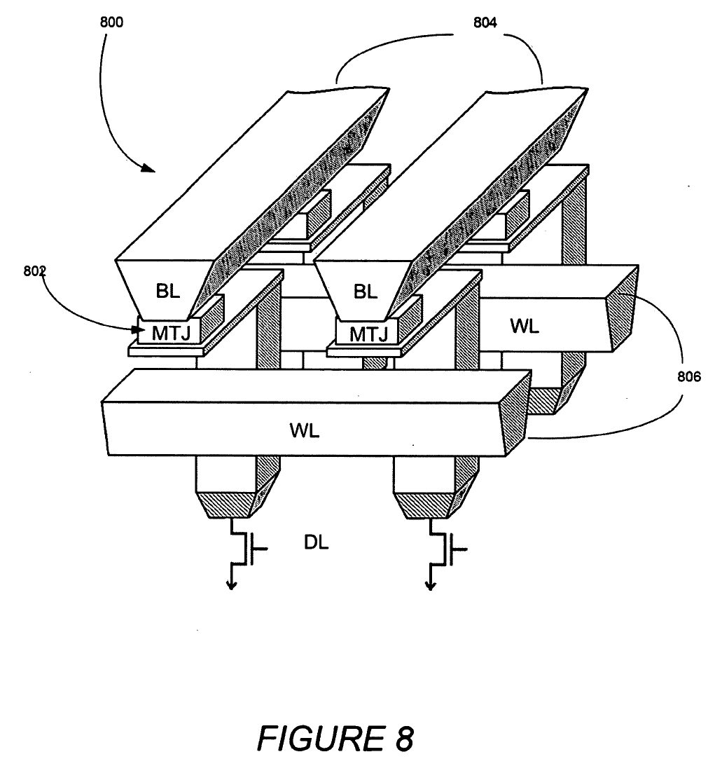

Referring next to FIG. 8, 2×2 MRAM device 800 in accordance with one embodiment of the invention is illustrated schematically. Within the device 800 magnetic storage elements 802 are energized by bit lines 804 and write lines 806. The magnetic storage elements each comprise a Magnetic Tunnel Junction (MTJ). As will be seen, the conductors 804 and 806 have a trapezoidal cross section. Thus, the MRAM array 800 may be used in a high density, low power MRAM device. One skilled in the art would realize that many of the components necessary to the functioning of the MRAM device 800 have been omitted so as not to obscure the invention. One example of such a component is a read circuit to read data stored in the device 800. Such components will be readily understood by one skilled in the art.

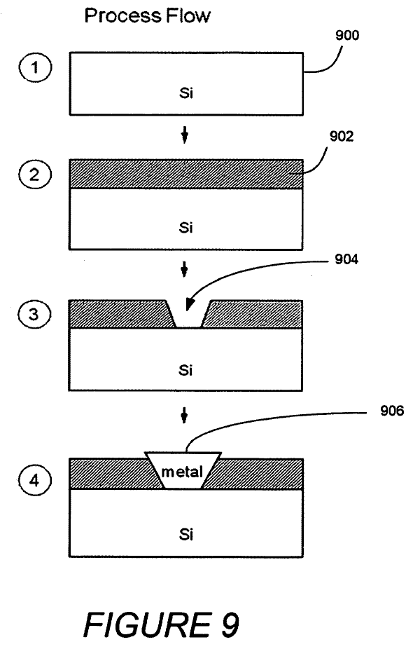

Referring to FIG. 9 of the drawings, there is shown an exemplary process flow to realize the MRAM array of FIG. 8, in accordance with one embodiment. In FIG. 9 the fabrication of semiconductor transistor structures has been excluded as it is a well understood process in the semiconductor industry. The steps to connect such a transistor to the memory cells are also not illustrated as that is readily understood by one skilled in the art.

Referring to FIG. 9, after the fabrication of the transistor and other relevant circuitry on a semiconductor substrate 900 such as Silicon, an insulating material 902 is deposited by thermal or non-thermal means on the substrate 900. Then a relevant lithographic technique is used to define the conductor pattern followed by a etching process which leads to a trench 904. A conducting material is then deposited followed by another lithographic step to define the conductor pattern. This conductive material is etched by standard etching processes. This results in a conductor 906 having a cross section of desired shape i.e. in accordance with the shapes shown in FIG. 7 of the drawings. The key processing step is defining the hole in the insulating material. This will vary depending on the desired shape of the conductor cross section.

1. A magnetic memory cell, comprising:
a magnetic memory element capable of being flipped between two stable spin orientations under the influence of an applied magnetic field; and
current-carrying conductors proximate the magnetic element to carry a current that induces said applied magnetic field, wherein the current-carrying conductors have a non-rectangular cross section.

2. The magnetic memory cell of claim 1, wherein the current carrying conductors have a triangular cross section.

3. The magnetic memory cell of claim 1, wherein the current carrying conductors have a trapezoidal cross section.

4. The magnetic memory cell of claim 1, wherein the magnetic element comprises a magneto-resistive magnetic element.

5. The magnetic memory cell of claim 4, wherein the magneto-resistive magnetic element comprises a Magnetic-Tunnel Junction (MTJ).

6. A magnetic memory device, comprising:
a plurality of magnetic memory cells, each comprising:
a magnetic memory element capable of being flipped between two stable spin orientations under the influence of an applied magnetic field; and
current-carrying conductors proximate the magnetic element to carry a current that induces said applied magnetic field, wherein the current-carrying conductors have a non-rectangular cross section; and
a read circuit for reading data from the selected magnetic memory cells.

7. The magnetic memory device of claim 6, wherein the current carrying conductors have a triangular cross section.

8. The magnetic memory device of claim 6, wherein the current carrying conductors have a trapezoidal cross section.

9. The magnetic memory device of claim 6, wherein the magnetic element comprises a magneto-resistive magnetic element.

10. The magnetic memory device of claim 9, wherein the magneto-resistive magnetic element comprises a Magnetic-Tunnel Junction (MTJ).
